(19) United States
(12) Patent Application Publication
(10) Pub. No.: US 2024/0431173 A1
(43) Pub. Date: Dec. 26, 2024

(54) DISPLAY DEVICE

(71) Applicant: Panasonic Automotive Systems Co., Ltd., Kanagawa (JP)

(72) Inventors: Koichi ITOH, Kanagawa Ken (JP); Ken SHIIBA, Ishikawa Ken (JP)

(73) Assignee: Panasonic Automotive Systems Co., Ltd., Kanagawa (JP)

(21) Appl. No.: 18/824,581

(22) Filed: Sep. 4, 2024

Related U.S. Application Data
(63) Continuation of application No. PCT/JP2022/037352, filed on Oct. 5, 2022.

(30) Foreign Application Priority Data
Mar. 25, 2022 (JP) 2022-050882

(51) Int. Cl. H10K 59/35; H01L 25/075; H10K 59/95

(52) U.S. Cl. CPC H10K 59/353; H10K 59/95; H01L 25/0753

(57) ABSTRACT

A display device includes a first transparent display including one or more first transmission areas and one or more first non-transmission areas that include one or more first light emitting elements; and a second transparent display bonded to the first transparent display. The second transparent display includes one or more second transmission areas and one or more second non-transmission areas that include one or more second light emitting elements. The one or more second non-transmission areas include a third non-transmission area. The one or more first non-transmission areas include a fourth non-transmission area overlapping the third non-transmission area. An area of the third non-transmission area is smaller than an area of the fourth non-transmission area. The third non-transmission area is hidden by the fourth non-transmission area when viewing the display device while facing the first transparent display.

### CROSS-REFERENCE TO RELATED APPLICATIONS

This application is a continuation of International Application No. PCT/JP2022/037352, filed on Oct. 5, 2022 which claims the benefit of priority of the prior Japanese Patent Application No. 2022-050882, filed on Mar. 25, 2022, the entire contents of which are incorporated herein by reference.

### FIELD

The present disclosure relates to a display device.

### BACKGROUND

A transparent display that performs information display on a window glass or a display window has been put into practical use. In such a transparent display, the background is seen through while display information is performed, and thus the installation place of the display device is less restricted.

Recently, there has been developed a transparent double-sided display capable of performing different information display on a front face and a back face while transmitting a background by bonding two such transparent displays (for example, JP 2021-82733 A).

In such a transparent double-sided display, it is desired to ensure high transmittance.

An object of the present disclosure is to provide a display device capable of securing high transmittance when two transparent double-sided displays are bonded to each other.

### SUMMARY

A display device includes a first transparent display and a second transparent display. The first transparent display includes one or more first transmission areas and one or more first non-transmission areas. The one or more first transmission areas transmit background light. The one or more first non-transmission areas include one or more first light emitting elements and do not transmit the background light. The one or more first light emitting elements perform information display ordered from an outside. The second transparent display is bonded to the first transparent display. The second transparent display includes one or more second transmission areas and one or more second non-transmission areas. The one or more second transmission areas transmit background light. The one or more second non-transmission areas include one or more second light emitting elements and do not transmit the background light. The one or more second light emitting elements perform information display ordered from an outside. The one or more second non-transmission areas include a third non-transmission area.

The one or more first non-transmission areas include a fourth non-transmission area overlapping the third non-transmission area. An area of the third non-transmission area is smaller than an area of the fourth non-transmission area. The third non-transmission area is hidden by the fourth non-transmission area when viewing the display device while facing the first transparent display.

### BRIEF DESCRIPTION OF THE DRAWINGS

FIG. 1A is a diagram for explaining a function of a transparent double-sided display according to a first embodiment;

FIG. 1B is a diagram illustrating an example of information observed by an observer from each face of the transparent double-sided display;

FIG. 2A is a diagram illustrating an example of a case where information is displayed on a transparent display;

FIG. 2B is a diagram for explaining a disadvantage of a conventional transparent double-sided display;

FIG. 3 is a diagram illustrating a schematic structure of the transparent double-sided display according to the first embodiment;

FIG. 4A is a first diagram illustrating an operation example of the transparent double-sided display according to the first embodiment;

FIG. 4B is a second diagram illustrating an operation example of the transparent double-sided display according to the first embodiment;

FIG. 5 is a diagram illustrating an example of a result of simulation of a change in the transmittance due to misalignment, occurring at the time of bonding, between the transparent double-sided display according to the first embodiment and a transparent double-sided display of a comparative example;

FIG. 6 is a diagram illustrating an example in which display areas are formed in a lattice shape;

FIG. 7 is a diagram illustrating an example in which display areas are formed in a dotted shape;

FIG. 8A is a first diagram illustrating a schematic structure of a first transparent display and a second transparent display according to a second embodiment;

FIG. 8B is a first diagram explaining a relationship between the misalignment and the transmittance that occurs when the first transparent display and the second transparent display in FIG. 8A are bonded to each other;

FIG. 9A is a second diagram illustrating a schematic structure of a first transparent display and a second transparent display according to the second embodiment;

FIG. 9B is a first diagram explaining a relationship between the misalignment and the transmittance that occurs when the first transparent display and the second transparent display in FIG. 9A are bonded to each other; and

FIG. 10 is a diagram illustrating a schematic structure of a transparent double-sided display according to a third embodiment.

### DETAILED DESCRIPTION

### First Embodiment

Hereinafter, a first embodiment of a display device according to the present disclosure will be described with reference to the drawings.

### (Function of Transparent Double-Sided Display)

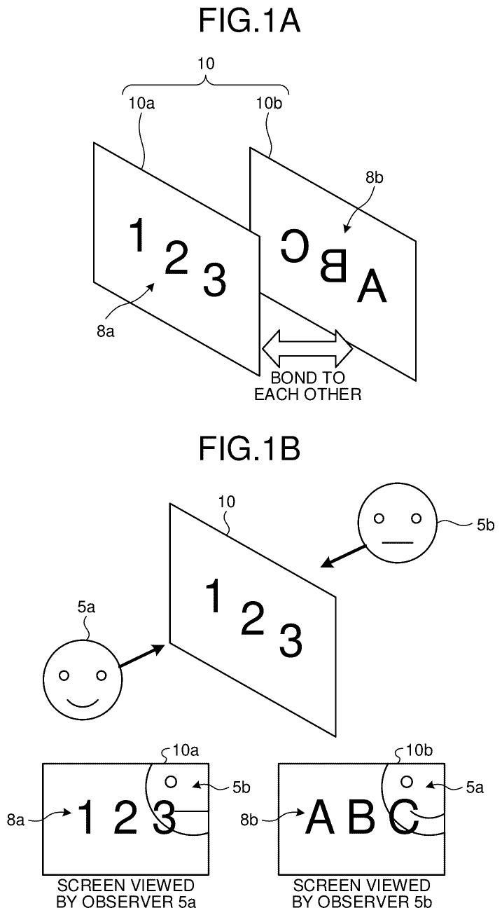

The function of a transparent double-sided display 10 will be described with reference to FIGS. 1A and 1B. FIG. 1A is a diagram for explaining a function of a transparent double-sided display according to a first embodiment. FIG. 1B is a diagram illustrating an example of information observed by an observer from each face of the transparent double-sided display.

The transparent double-sided display 10 has a structure in which a first transparent display 10a and a second transparent display 10b are bonded to each other. Both of the first transparent display 10a and the second transparent display 10b are configured by a display device having a self-emitting display element. The first transparent display 10a and the second transparent display 10b can each perform different video display. Incidentally, the first transparent display 10a and the second transparent display 10b are bonded to each other by, for example, a transparent adhesive used for bonding an optical element such as a lens. Therefore, the brightness of the display devices that emit light themselves is not impaired.

Illustrated in FIG. 1A is an example in which the first transparent display 10a performs video display 8a of “123”, and the second transparent display 10b performs video display 8b of “ABC”.

As illustrated in FIG. 1B, an observer 5a of the first transparent display 10a can visually recognize the video display 8a and the background of the first transparent display 10a. Meanwhile, an observer 5b of the second transparent display 10b can visually recognize the video display 8b and the background of the second transparent display 10b.

In the case of FIG. 1B, since the observers 5a and 5b are simultaneously viewing the transparent double-sided display 10, the observer 5a visually recognizes the observer 5b in the background of the video display 8a. In addition, the observer 5c visually recognizes the observer 5a in the background of the video display 8b.

### (Disadvantage of Conventional Transparent Double-Sided Display)

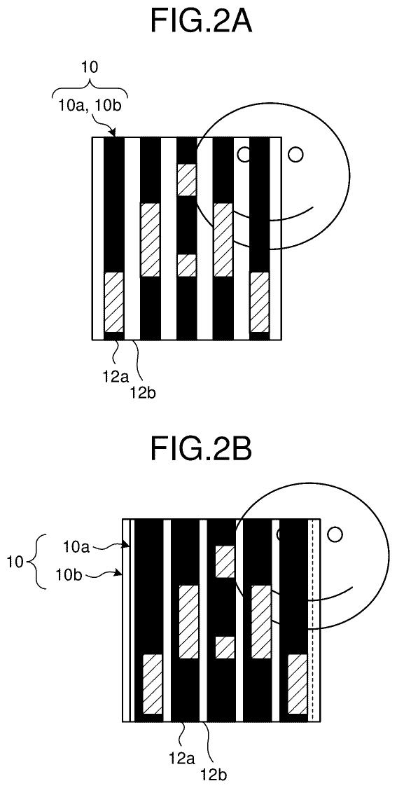

A disadvantage of the conventional transparent double-sided display will be described with reference to FIGS. 2A and 2B. FIG. 2A is a diagram illustrating an example of a case where information display is performed on a transparent display. FIG. 2B is a diagram illustrating a disadvantage of the conventional transparent double-sided display.

As illustrated in FIG. 2A, a first transparent display 10a included in a transparent double-sided display 10 has a configuration in which display areas 12a and transmission areas 12b are alternately arranged in a stripe pattern.

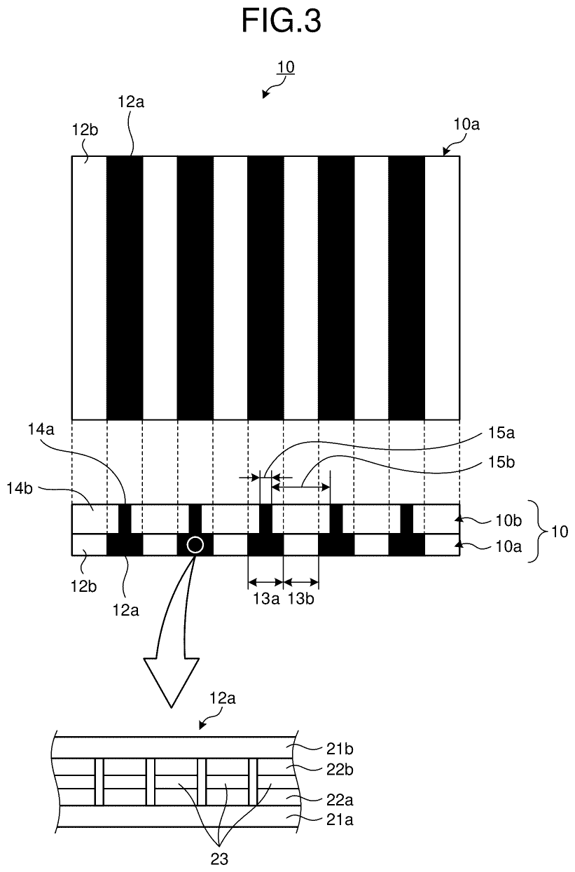

A display area 12a is an area where video display is performed. In the display area 12a, a light emitting element that forms a video, a drive circuit that performs ON/OFF control of the light emitting element, a transparent electrode that applies a voltage to the light emitting element, and others are formed. Details will be described later (see FIG. 3). Note that, since various circuits and elements for forming a video are mounted, the display area 12a is a non-transmission area that does not transmit the background light. In addition, the display area 12a may have an area where no circuits or elements are mounted. Since these areas transmit the background light, the display area 12a may transmit a part of the background light. As described above, the display areas 12a are not limited to areas that do not transmit the background light at all but are, for example, areas having a lower transmittance than the transmission areas 12b.

A transmission area 12b is an area where no circuit elements or the like related to video display are disposed. Therefore, the transmission area 12b transmits the background light. An observer can visually recognize the background through the transmission areas 12b.

In the example of FIG. 2A, the observer can simultaneously visually recognize video display of “A” displayed in the display areas 12a and the background through the transmission areas 12b.

The transparent double-sided display 10 is formed by bonding the first transparent display 10a and the second transparent display 10b. More specifically, the bonding is performed in such a manner that the display areas 12a and the transmission areas 12b of the first transparent display 10a and display areas and transmission areas of the first transparent display 10a overlap each other, respectively. Note that the structure of the second transparent display 10b is the same as the structure of the first transparent display 10a. When the first transparent display 10a and the second transparent display 10b are bonded to each other, misalignment may occur between the first transparent display 10a and the second transparent display 10b.

Illustrated in FIG. 2B is an example in which misalignment has occurred in the width direction of the display areas 12a when the first transparent display 10a and the second transparent display 10b are bonded to each other. In the case of FIG. 2B, the second transparent displays 10b are shifted to the left side in the drawing. In this case, when viewed from an observer of the first transparent display 10a, the area of the transmission areas 12b is reduced. Therefore, the background seen beyond the transmission areas 12b is darker.

### (Structure of Transparent Double-Sided Display of Embodiment)

The structure of a transparent double-sided display 10 of a first embodiment will be described with reference to FIG. 3. FIG. 3 is a diagram illustrating a schematic structure of the transparent double-sided display according to the first embodiment.

The transparent double-sided display 10 of the present embodiment has a structure in which a first transparent display 10a and a second transparent display 10b are bonded to each other. Note that the transparent double-sided display 10 is an example of a display device in the present disclosure.

The first transparent display 10a has a structure in which one or more display areas 12a and one or more transmission areas 12b are alternately arranged in a stripe pattern. The widths 13a of the display areas 12a are all equal, and the widths 13b of the transmission areas 12b are all equal. Note that the one or more display areas 12a are an example of one or more first non-transmission areas in the present disclosure. The one or more transmission areas 12b are an example of one or more first transmission areas in the present disclosure.

The second transparent display 10b has a structure in which one or more display areas 14a and one or more transmission areas 14b are alternately arranged in a stripe pattern. The widths 15a of the display areas 14a are all equal, and the widths 15b of the transmission areas 14b are all equal. Incidentally, the width 15a of a display area 14a of the second transparent display 10b is shorter than the width 13a of a display area 12a of the first transparent display 10a. Meanwhile, the width 15b of a transmission area 14b of the second transparent display 10b is longer than the width 13b of a transmission area 12b of the first transparent display 10a. Therefore, the area of the display areas 14a of the second transparent display 10b is smaller than the area of the display areas 12a of the first transparent display 10a. Note that the one or more display areas 14a are an example of one or more second non-transmission areas in the present disclosure. The one or more transmission areas 14b are an example of one or more second transmission areas in the present disclosure.

The display areas 12a of the first transparent display 10a and the display areas 14a of the second transparent display 10b are bonded to each other in such a manner as to overlap each other while facing the transparent double-sided display 10. When viewing the transparent double-sided display 10 while facing the first transparent display 10a side, the display areas 14a of the second transparent display 10b are hidden behind the display areas 12a of the first transparent display 10a. In other words, the one or more second non-transmission areas include a third non-transmission area, the one or more first non-transmission areas includes a fourth non-transmission area overlapping the third non-transmission area, and an area of the third non-transmission area is smaller than an area of the fourth non-transmission area. Further, when viewing the transparent double-sided display 10 while facing the first transparent display 10a, the third non-transmission area is hidden behind the fourth non-transmission area.

As illustrated in FIG. 3, in the display area 12a of the first transparent display 10a, transparent electrodes 22a, light emitting elements 23, and transparent electrodes 22b are stacked and arranged in the order mentioned from the front face side in a state where the front face and the back face are sandwiched between glass substrates 21a and 21b. The light emitting elements 23 are an example of first light emitting elements in the present disclosure. In other words, the first non-transmission areas include one or more first light emitting elements performing information display ordered from the outside. Further, although illustration in drawings is omitted, the display area 14a of the second transparent display 10b also has the same configuration as illustrated in FIG. 3. In other words, the second non-transmission areas include one or more second light emitting elements performing information display ordered from the outside. In other words, light emitting elements that are included in the second transparent display 10b and not illustrated in the drawings are an example of second light emitting elements in the present disclosure. The transparent electrodes 22a and 22b are an example of first transparent electrodes, and electrodes similarly stacked and arranged in the display area 14a of the second transparent display 10b are an example of second electrodes.

Via the transparent electrodes 22a and the transparent electrodes 22b, voltages for causing the light emitting elements 23 to emit light are applied. The transparent electrodes 22a and 22b constitute anodes and cathodes, respectively. The transparent electrodes 22a and the transparent electrodes 22b do not block the traveling of the light emitted from the light emitting elements 23 when causing the light emitting element to emit the light so that it is possible to prevent the display of the transparent double-sided display 10 from being darken.

The light emitting elements 23 form a video by emitting light by themselves. The light emitting elements 23 are, for example, organic EL elements. Note that, although not distinguished in FIG. 3, a light emitting element 23 has a structure in which, for example, a red light emitting element that emits red light, a green light emitting element that emits green light, and a blue light emitting element that emits blue light are regularly arrayed.

Although not illustrated in FIG. 3, a switching circuit including, for example, a transistor for driving a light emitting element 23 is further mounted in a display area 12a of the first transparent display 10a.

As the light emitting elements 23 used in the display areas 12a of the first transparent display 10a and the display areas 14a of the second transparent display 10b, for example, LEDs may be used other than organic EL elements. A display using LEDs as light emitting elements 23 is called a microLED display. In a microLED display, a red LED, a green LED, and a blue LED are regularly arrayed as light emitting elements 23.

### (Operation of Transparent Double-Sided Display of Embodiment)

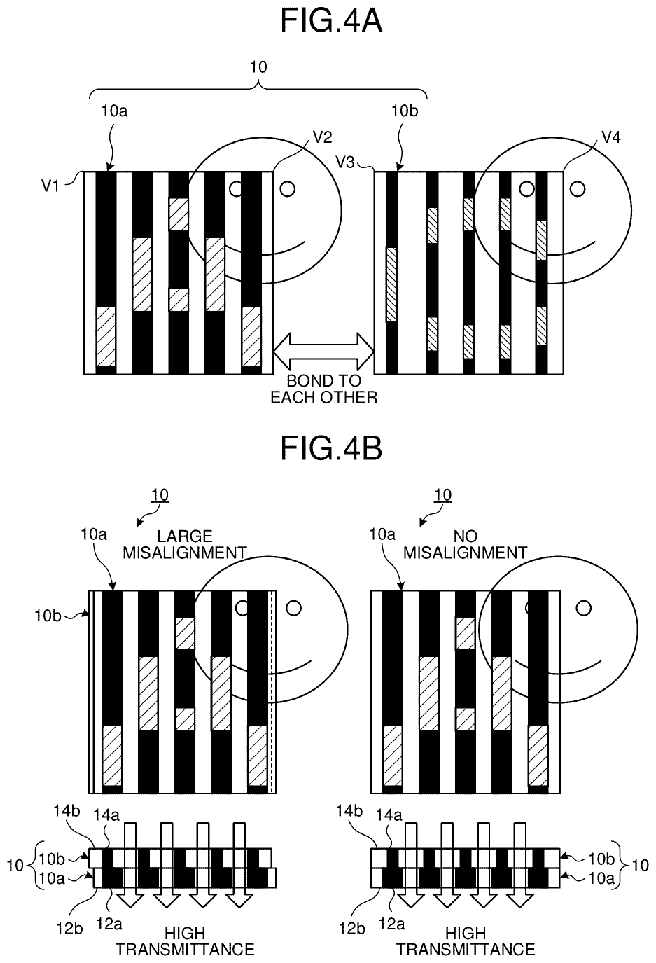

The structure of the transparent double-sided display 10 of the first embodiment will be described with reference to FIGS. 4A and 4B. FIG. 4A is a first diagram illustrating an operation example of the transparent double-sided display according to the first embodiment. FIG. 4B is a second diagram illustrating an operation example of the transparent double-sided display according to the first embodiment.

Illustrated in FIG. 4A is an example in which “A” is displayed on the first transparent display 10a and “C” is displayed on the second transparent display 10b in the transparent double-sided display 10 according to the first embodiment. In this case, the first transparent display 10a and the second transparent display 10b are bonded to each other such that the upper left vertex V1 of the first transparent display 10a and the upper right vertex V4 of the second transparent display 10b coincide with each other and that the upper right vertex V2 of the first transparent display 10a and the upper left vertex V3 of the second transparent display 10b coincide with each other.

As described above, since the display areas 14a of the second transparent display 10b have shorter widths than the display areas 12a of the first transparent display 10a do, “C” displayed on the second transparent display 10b is displayed darker than “A” displayed on the first transparent display 10a.

Illustrated in FIG. 4B is an example of a case where misalignment in a direction orthogonal to the display areas 12a has occurred when the first transparent display 10a and the second transparent display 10b are bonded to each other in the transparent double-sided display 10 according to the first embodiment.

The left diagram of FIG. 4B illustrates an example of a case where the misalignment is large. Meanwhile, the right diagram of FIG. 4B illustrates an example of a case where there is no misalignment.

In the right diagram of FIG. 4B, since the widths of the display areas 14a of the second transparent display 10b are smaller than the widths of the display areas 12a of the first transparent display 10a, the transmission areas 12b of the first transparent display 10a transmit the background light over the entire areas as indicated by arrows in the drawing.

Moreover, in the left diagram of FIG. 4B, with the positions of the display areas 14a of the second transparent display 10b shifted, the overlapping positions between the display areas 12a of the first transparent display 10a and the display areas 14a of the second transparent display 10b are moved. However, since the widths of the display areas 14a of the second transparent display 10b are smaller than the widths of the display areas 12a of the first transparent display 10a, the display areas 14a of the second transparent display 10b remain hidden by the display areas 12a of the first transparent display 10a while facing the first transparent display 10a. Therefore, the transmission areas 12b of the first transparent display 10a transmit the background light over the entire areas as indicated by arrows in the drawing. Therefore, when the first transparent display 10a and the second transparent display 10b are bonded to each other, the transparent double-sided display 10 according to the first embodiment maintains the same transmittance even in a case where misalignment along the width direction of the display areas 12a occurs. In other words, even in a case where misalignment occurs when the first transparent display 10a and the second transparent display 10b are bonded to each other, the brightness of the background seen through the transparent double-sided display 10 does not change. Furthermore, the brightness of the background does not change in either cases where the transparent double-sided display 10 is viewed from the first transparent display 10a side or viewed from the second transparent display 10b side.

### (Transmittance of Transparent Double-Sided Display of Embodiment)

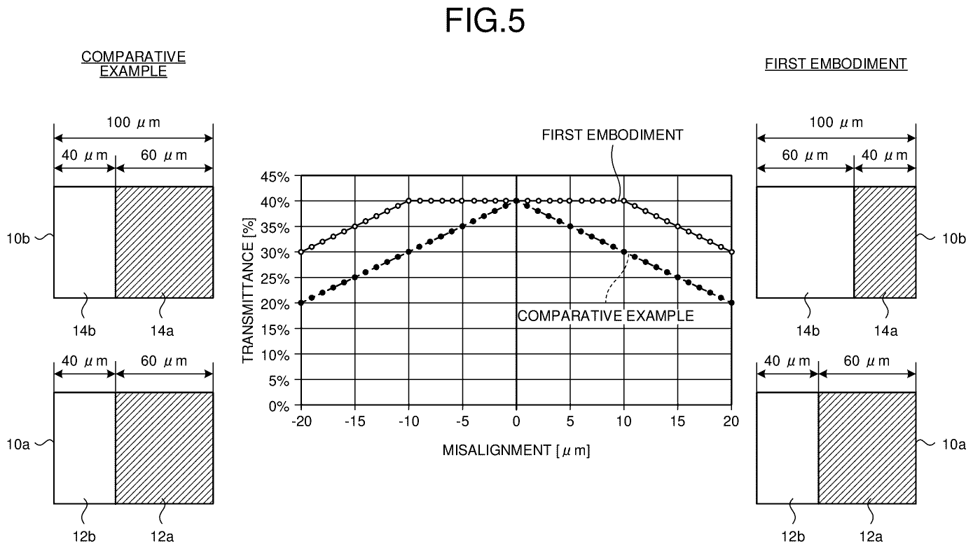

With reference to FIG. 5, the relationship between the size of the misalignment occurring when the first transparent display 10a and the second transparent display 10b are bonded to each other and the transmittance of the first transparent display 10a will be described. FIG. 5 is a diagram illustrating an example of a result of simulation of a change in the transmittance due to misalignment, occurring at the time of bonding, between the transparent double-sided display according to the first embodiment and a transparent double-sided display of a comparative example.

A graph illustrated in FIG. 5 illustrates the relationship between the size of misalignment between the first transparent display 10a and the second transparent display 10b in the width direction of the display areas 12a and the transmittance of the first transparent display 10a when the first transparent display 10a and the second transparent display 10b are bonded to each other in the transparent double-sided display 10 of the present embodiment. Incidentally, the width of a display area 12a of the first transparent display 10a is 60 μm, and the width of a transmission area 12b is 40 μm. The width of a display area 14a of the second transparent display 10b is 40 μm, and the width of a transmission area 14b is 60 μm.

In addition, the graph illustrated in FIG. 5 illustrates the relationship between the size of misalignment between a first transparent display 10a and a second transparent display 10b of the comparative example in the width direction of display areas 12a and the transmittance of the first transparent display 10a when the first transparent display 10a and the second transparent display 10b are bonded to each other. Incidentally, the width of a display area 12a of the first transparent display 10a is 60 μm, and the width of a transmission area 12b is 40 μm. The width of a display area 14a of the second transparent display 10b is 60 μm, and the width of a transmission area 14b is 40 μm.

In a case where the first transparent display 10a and the second transparent display 10b are bonded to each other without misalignment, both of the transparent double-sided displays 10 indicate transmittance of 40%. Moreover, in a case where misalignment of the display areas 12a in the width direction occurs, the transmittance decreases in proportion to the size of the misalignment in the comparative example. Note that, in the present embodiment, the state in which the first transparent display 10a and the second transparent display 10b are bonded to each other without misalignment indicates a state in which the bonding is performed with the center line of a display area 12a in the width direction and the center line of a display area 14a in the width direction coinciding each other.

Meanwhile, in the transparent double-sided display 10 of the present embodiment, a transmittance of 40% is maintained as long as the misalignment of a display area 12a in the width direction is less than or equal to 10 μm. When the misalignment of a display area 12a in the width direction exceeds 10 μm, the transmittance decreases in proportion to the size of the misalignment.

As described above, the transparent double-sided display 10 of the present embodiment has an allowable range for preventing a decrease in the transmittance with respect to the misalignment of the display areas 12a in the width direction. In the case of the example illustrated in FIG. 5, this allowable range is ±10 μm.

According to the transparent double-sided display 10 of the first embodiment, the area of the display areas 12a formed in the first transparent display 10a is larger than the area of the display areas 14a formed in the second transparent display 10b. Therefore, when the same image is displayed on the first transparent display 10a and the second transparent display 10b, the image displayed on the first transparent display 10a is brighter. Therefore, it is desirable to set the orientation of the transparent double-sided display 10 depending on the illuminance of the environment in which the transparent double-sided display 10 is used. For example, it is desirable to use the transparent double-sided display 10 with the first transparent display 10a directed to the side facing the outdoors where the illuminance of the display pane is high and the second transparent display 10b directed to the side facing the indoor where the illuminance of the display pane is low.

### Operation and Effect of First Embodiment

As described above, the transparent double-sided display 10 (display device) of the first embodiment includes the first transparent display 10a including the one or more transmission areas 12b (first transmission areas) that transmit the background light and the one or more display areas 12a (first non-transmission areas) that include one or more first light emitting elements and do not transmit the background light, the one or more first light emitting elements performing information display ordered from the outside, and the second transparent display 10b that is bonded to the first transparent display 10a, and include the one or more transmission areas 14b (second transmission areas) that transmit the background light and the one or more display areas 14a (second non-transmission areas) that include one or more second light emitting element and do not transmit the background light, the one or more second light emitting elements performing information display ordered from the outside, the one or more second non-transmission areas include a third non-transmission area, the one or more first non-transmission areas include a fourth non-transmission area overlapping the third non-transmission area, the area of the third non-transmission area is smaller than the area of the fourth non-transmission, and bonding is performed in such a manner that the third non-transmission area is hidden by the fourth non-transmission when viewing the transparent double-sided display 10 while facing the first transparent display 10a. Therefore, high transmittance can be ensured when the first transparent display 10a and the second transparent display 10b are bonded to each other.

In the transparent double-sided display 10 of the first embodiment, the one or more display areas 12a (first non-transmission areas) of the first transparent display 10a and the one or more display areas 14a (second non-transmission areas) of the second transparent display 10b are each formed in a stripe shape. Therefore, high transmittance can be ensured when the first transparent display 10a and the second transparent display 10b are bonded to each other.

Furthermore, in the transparent double-sided display 10 of the first embodiment, a side including the display areas 14a having a smaller total area out of the display areas 12a (first non-transmission areas) and the display areas 14a (second non-transmission areas) is disposed on a side where surrounding illuminance is lower. In other words, in a case where the total area of the one or more first non-transmission areas is larger than the total area of the one or more second non-transmission areas, the second transparent display 10b is disposed on the side where surrounding illuminance is lower. Therefore, a bright display image is displayed on the first transparent display 10a in which a display image is bright, and a dark display image is displayed on the second transparent display 10b in which a display image is dark, and thus viewers viewing each display image can view highly visible display images having brightness corresponding to the environment. Incidentally, in a case where the total area of the display areas 12a is smaller among the display areas 12a and the display areas 14a, the first transparent display 10a including the display areas 12a may be disposed on the side where surrounding illuminance is lower.

### Modification of First Embodiment

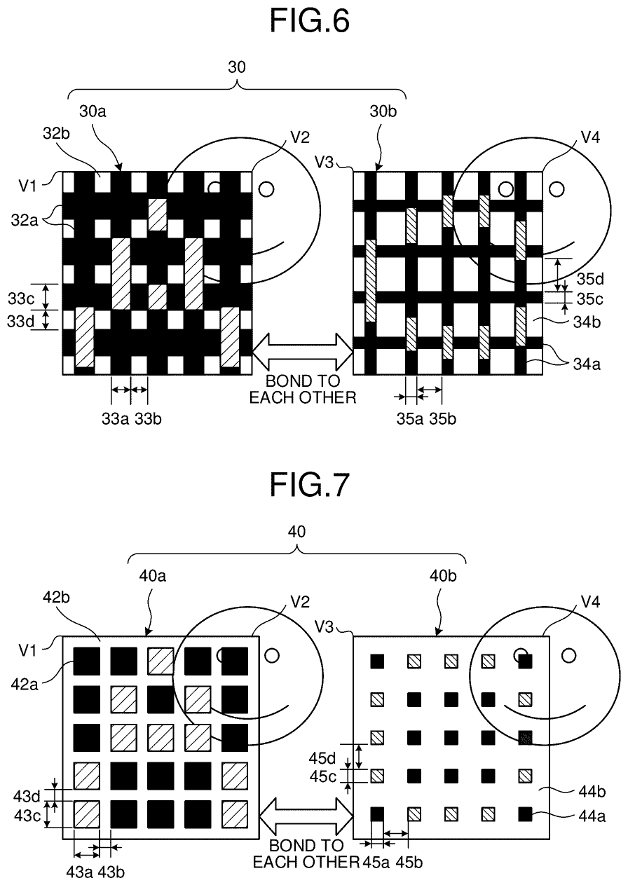

In the first embodiment, the example in which the display areas 12a and the transmission areas 12b are formed in a stripe pattern has been described; however, the form of the display areas 12a and the transmission areas 12b is not limited to the stripe pattern. Hereinafter, an example in which the display areas 12a and the transmission areas 12b are formed in different forms will be described with reference to FIGS. 6 and 7. FIG. 6 is a diagram illustrating an example in which display areas are formed in a lattice shape. FIG. 7 is a diagram illustrating an example in which display areas are formed in a dotted shape.

Illustrated in FIG. 6 is an example in which “A” is displayed on a first transparent display 30a and “C” is displayed on a second transparent display 30b in a transparent double-sided display 30 according to a modification of the first embodiment. In this case, the first transparent display 30a and the second transparent display 30b are bonded to each other such that the upper left vertex V1 of the first transparent display 30a and the upper right vertex V4 of the second transparent display 30b coincide with each other and that the upper right vertex V2 of the first transparent display 30a and the upper left vertex V3 of the second transparent display 30b coincide with each other.

In the first transparent display 30a, display areas 32a having a vertical and horizontal lattice shape are formed. A display area 32a includes a display area having a width 33a extending along the vertical direction of the first transparent display 30a and a display area having a width 33c extending along the horizontal direction of the first transparent display 30a. A transmission area 32b having a horizontal width 33b and a vertical width 33d is formed in a gap part of the lattice-shaped display area 32a. Note that the display areas 32a are an example of the first non-transmission area in the present disclosure. The transmission areas 32b are an example of the first transmission area in the present disclosure.

Furthermore, in the second transparent display 30b, display areas 34a having a vertical and horizontal lattice shape are formed. A display area 34a includes a display area having a width 35a extending along the vertical direction of the second transparent display 30b and a display area having a width 35c extending along the horizontal direction of the second transparent display 30b. A transmission area 34b having a horizontal width 35b and a vertical width 35d is formed in a gap part of the lattice-shaped display area 34a. Note that the display areas 34a are an example of the second non-transmission area in the present disclosure. The transmission areas 34b are an example of the second transmission area in the present disclosure.

In FIG. 6, the width 35a of a display area 34a of the second transparent display 30b is shorter than the width 33a of a display area 32a of the first transparent display 30a. Meanwhile, the width 35c of a display area 34a of the second transparent display 30b is shorter than the width 33c of a display area 32a of the first transparent display 30a. Therefore, the area of the display areas 34a of the second transparent display 30b is smaller than the area of the display areas 32a of the first transparent display 30a.

When the first transparent display 30a and the second transparent display 30b are bonded to each other, the lattice-shaped display areas 34a of the second transparent display 30b are hidden behind the lattice-shaped display areas 32a of the first transparent display 30a when viewed from the first transparent display 30a side.

Therefore, when the first transparent display 30a and the second transparent display 30b are bonded to each other, even in a case where misalignment along a width direction of the vertical and horizontal lattice-shaped stripes occurs, the transparent double-sided display 30 maintains the same transmittance. In other words, even in a case where misalignment occurs when the first transparent display 30a and the second transparent display 30b are bonded to each other, the brightness of the background seen through the transparent double-sided display 30 does not change. Furthermore, the brightness of the background does not change in either cases where the transparent double-sided display 30 is viewed from the first transparent display 30a side or viewed from the second transparent display 30b side.

Illustrated in FIG. 7 is an example in which “A” is displayed on a first transparent display 40a and “C” is displayed on a second transparent display 40b in a transparent double-sided display 40 according to a modification of the first embodiment. In this case, the first transparent display 40a and the second transparent display 40b are bonded to each other such that the upper left vertex V1 of the first transparent display 40a and the upper right vertex V4 of the second transparent display 40b coincide with each other and that the upper right vertex V2 of the first transparent display 40a and the upper left vertex V3 of the second transparent display 40b coincide with each other.

In the first transparent display 40a, display areas 42a having a rectangular dot shape are formed. The display area 42a includes a plurality of rectangular areas having a width 43a and a height 43c. A transmission area 42b having a lateral width 43b and a vertical width 43d is formed in a gap part of the display area 42a. Note that the display areas 42a are an example of the first non-transmission area in the present disclosure. The transmission areas 42b are an example of the first transmission area in the present disclosure.

In the second transparent display 40b, display areas 44a having a rectangular dot shape are formed. The display area 44a includes a plurality of rectangular areas having a width 45a and a height 45c. A transmission area 44b having a horizontal width 45b and a vertical width 45d is formed in a gap part of the display area 44a. Note that the display areas 44a are an example of the second non-transmission area in the present disclosure. The transmission areas 44b are an example of the second transmission area in the present disclosure.

In FIG. 7, the width 45a of each dot included in a display area 44a of the second transparent display 40b is smaller than the width 43a of the display area 42a of the first transparent display 40a. Meanwhile, the height 45c of a display area 44a of the second transparent display 40b is shorter than the height 43c of a display area 42a of the first transparent display 40a. Therefore, the area of each dot included in the display area 44a of the second transparent display 40b is smaller than the area of each dot included in the display area 42a of the first transparent display 40a.

When the first transparent display 40a and the second transparent display 40b are bonded to each other, all the dots included in the display areas 44a of the second transparent display 40b are hidden behind the dots included in the display area 42a of the first transparent display 40a when viewed from the first transparent display 40a side.

Therefore, when the first transparent display 40a and the second transparent display 40b are bonded to each other, even in a case where misalignment occurs in the vertical direction or in the horizontal direction of the dots included in the display areas 44a, the transparent double-sided display 40 maintains the same transmittance. In other words, even in a case where misalignment occurs when the first transparent display 40a and the second transparent display 40b are bonded to each other, the brightness of the background seen through the transparent double-sided display 40 does not change. Furthermore, the brightness of the background does not change in either cases where the transparent double-sided display 40 is viewed from the first transparent display 40a side or viewed from the second transparent display 40b side.

Note that the patterns constituting the display areas of the first transparent display and the display areas of the second transparent display are not limited to the examples described herein. That is, even in a case other than the lattice-shaped pattern or the dot-shaped pattern, it is only required that the area of the display areas of the second transparent display be formed to be smaller than the area of the display areas of the first transparent display and that the display areas formed in the second transparent display be hidden when viewed from the first transparent display side when the first transparent display and the second transparent display are bonded to each other.

### Operation and Effect of Modification of First Embodiment

As described above, in the transparent double-sided display 30 of the modification of the first embodiment, the one or more display areas 32a (first non-transmission areas) and the one or more display areas 34a (second non-transmission areas) are each formed in a lattice shape. Therefore, high transmittance can be ensured when the first transparent display 30a and the second transparent display 30b are bonded to each other.

Furthermore, in the transparent double-sided display 40 according to the modification of the first embodiment, the one or more display areas 42a (first non-transmission areas) and the one or more display areas 44a (second non-transmission areas) are each formed in a dotted shape. Therefore, high transmittance can be ensured when the first transparent display 40a and the second transparent display 40b are bonded to each other.

### Second Embodiment

Hereinafter, a second embodiment of a display device according to the present disclosure will be described with reference to the drawings.

### Structure of Transparent Double-Sided Display of Embodiment

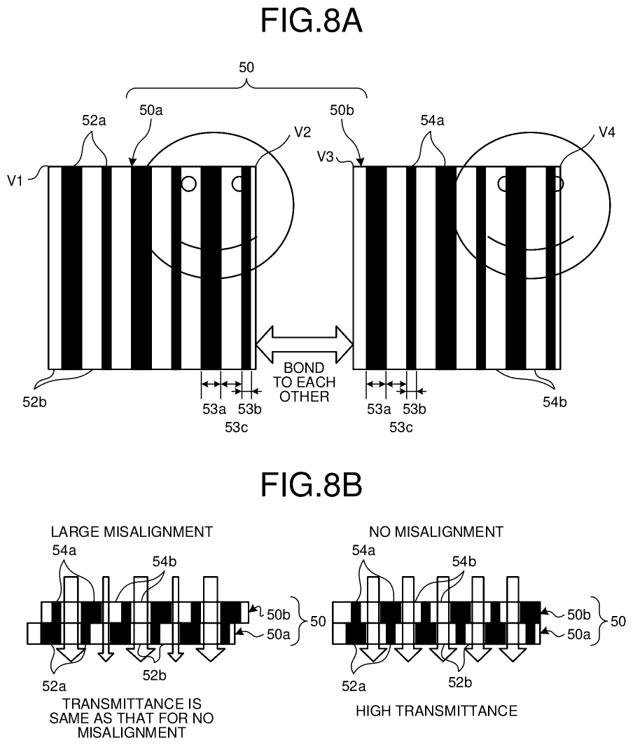

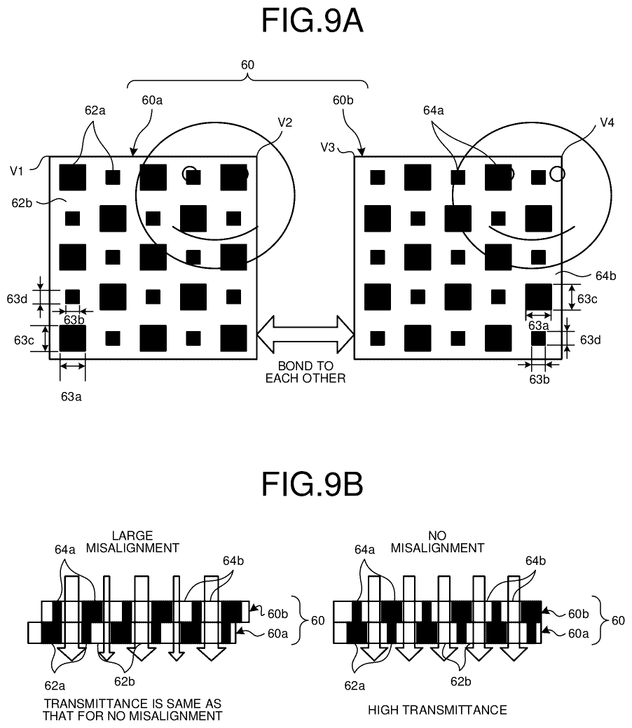

The structures of transparent double-sided displays 50 and 60 of the second embodiment will be described with reference to FIGS. 8A and 8B and FIGS. 9A and 9B. FIG. 8A is a first diagram illustrating a schematic structure of a first transparent display and a second transparent display according to the second embodiment. FIG. 8B is a first diagram explaining a relationship between the misalignment and the transmittance that occurs when the first transparent display and the second transparent display in FIG. 8A are bonded to each other. FIG. 9A is a second diagram illustrating a schematic structure of a first transparent display and a second transparent display according to the second embodiment. FIG. 9B is a first diagram explaining a relationship between the misalignment and the transmittance that occurs when the first transparent display and the second transparent display in FIG. 9A are bonded to each other.

Illustrated in FIG. 8A is an example of patterns of display areas and transmission areas formed in each of a first transparent display 50a and a second transparent display 50b include in the transparent double-sided display 50 according to the second embodiment.

Stripe-shaped display areas having exactly the same repetitive pattern are formed in the first transparent display 50a and the second transparent display 50b. Display areas 52a formed in the first transparent display 50a include display areas having a width 53a and display areas having a width 53b which is smaller than the width 53a. In other words, the one or more first non-transmission areas include a plurality of first non-transmission areas including a fifth non-transmission area and a sixth non-transmission area that is different in size from the fifth non-transmission area, and the plurality of first non-transmission areas form a first repetitive pattern. In the first transparent display 50a, transmission areas 52b having a width 53c adjacent to the stripes constituting the display areas 52a are formed.

Display areas 54a formed in the second transparent display 50b include display areas having a width 53a and display areas having a width 53b which is smaller than the width 53a. In the second transparent display 50b, transmission areas 54b having the width 53c adjacent to the stripes constituting the display areas 54a are formed. In other words, the one or more second non-transmission areas include a plurality of second non-transmission areas including a seventh non-transmission area and a eighth non-transmission area that is different in size from the seventh non-transmission area, and the plurality of second non-transmission areas form a second repetitive pattern. Further, areas of the one or more first transmission areas located in the first repetitive pattern is equal to areas of the one or more second transmission areas located in the second repetitive pattern.

The transparent double-sided display 50 is formed by bonding in such a manner that the upper left vertex V1 of the first transparent display 50a and the upper right vertex V4 of the second transparent display 50b coincide with each other and that the upper right vertex V2 of the first transparent display 50a and the upper left vertex V3 of the second transparent display 50b coincide with each other. At this point, the bonding is performed in such a manner that the display areas of the first transparent display 50a having the width 53a and the display areas of the second transparent display 50b having the width 53b overlap each other.

By bonding the first transparent display 50a and the second transparent display 50b in this manner, as illustrated in FIG. 8B, even in a case where misalignment occurs at the time of bonding the first transparent display 50a and the second transparent display 50b, the amount of background light transmitted by the transparent double-sided display 50 is constant. That is, even in a case where misalignment occurs at the time of bonding the first transparent display 50a and the second transparent display 50b, the transmittance of the transparent double-sided display 50 is kept constant.

Next, with reference to FIGS. 9A and 9B, an example in which a similar function is implemented by a pattern other than the stripes will be described.

Stripe-shaped display areas having exactly the same repetitive pattern are formed in a first transparent display 60a and a second transparent display 60b included in the transparent double-sided display 60 illustrated in FIG. 9A. Display areas 62a formed in the first transparent display 50a include display areas having a width 63a and a height 63c and display areas having a width 63b which is smaller than the width 63a and a height 63d which is smaller than the height 63c. In the first transparent display 60a, a transmission area 62b adjacent to the dots constituting the display areas 62a is formed.

Display areas 64a formed in the second transparent display 60b include display areas having a width 63a and a height 63c and display areas having a width 63b which is smaller than the width 63a and a height 63d which is smaller than the height 63c. In the second transparent display 60b, a transmission area 64b adjacent to the dots constituting the display areas 64a is formed.

The transparent double-sided display 60 is formed by bonding in such a manner that the upper left vertex V1 of the first transparent display 60a and the upper right vertex V4 of the second transparent display 60b coincide with each other and that the upper right vertex V2 of the first transparent display 60a and the upper left vertex V3 of the second transparent display 60b coincide with each other. At this point, the dots of the first transparent display 60a having the width 63a and the dots of the second transparent display 60b having the width 63b overlap each other, and the dots of the first transparent display 60a having the width 63b and the dots of the second transparent display 60b having the width 63a overlap each other.

By bonding the first transparent display 60a and the second transparent display 60b in this manner, as illustrated in FIG. 9B, even in a case where misalignment occurs at the time of bonding the first transparent display 60a and the second transparent display 60b, the amount of background light transmitted by the transparent double-sided display 60 is constant. That is, even in a case where misalignment occurs at the time of bonding the first transparent display 60a and the second transparent display 60b, the transmittance of the transparent double-sided display 60 is kept constant.

### Operation and Effect of Second Embodiment

As described above, in the transparent double-sided display 50 of the second embodiment, the display areas 52a of the first transparent display 50a include the plurality of first non-transmission areas including the fifth non-transmission area and the sixth non-transmission area that is different in size from the fifth non-transmission area, and the plurality of first non-transmission areas form the first repetitive pattern, the display areas 54a of the second transparent display 50b include the plurality of second non-transmission areas including the seventh non-transmission area and the eighth non-transmission area that is different in size from the seventh non-transmission area, and the plurality of second non-transmission areas form the second repetitive pattern, and the areas of the one or more transmission areas 52b (first transmission areas) located in the first repetitive patterns formed by the display areas 52a are equal to the areas of the one or more transmission areas 54b (second transmission areas) located in the second repetitive patterns. Therefore, even in a case where misalignment occurs at the time of bonding the first transparent display 50a and the second transparent display 50b, the transmittance of the transparent double-sided display 50 can be kept constant. In addition, since the total area of the display areas 52a formed in the first transparent display 50a and the total area of the display areas 54a formed in the second transparent display 50b can be made equal to each other, the brightness of a display image can be made equal between the case where the transparent double-sided display 50 is viewed from the first transparent display 50a side and the case where the transparent double-sided display 50 is viewed from the second transparent display 50b side.

In addition, in the transparent double-sided display 60 of the second embodiment, the display areas 62a of the first transparent display 60a and the display areas 64a of the second transparent display 60b each have a repetitive pattern of a plurality of different sizes, and the total area of the transmission areas 62b formed between the repetitive pattern formed by the display areas 62a is equal to the total area of the transmission areas 64b formed between the repetitive pattern formed by the display areas 64a. Therefore, even in a case where misalignment occurs at the time of bonding the first transparent display 60a and the second transparent display 60b, the transmittance of the transparent double-sided display 60 can be kept constant. In addition, since the total area of the display areas 62a formed in the first transparent display 60a and the total area of the display areas 64a formed in the second transparent display 60b can be made equal to each other, the brightness of a display image can be made equal between the case where the transparent double-sided display 60 is viewed from the first transparent display 60a side and the case where the transparent double-sided display 60 is viewed from the second transparent display 60b side. Note that, in FIG. 9A, only display areas of five rows and five columns are extracted and displayed from the display areas formed in each of the first transparent display 60a and the second transparent display 60b. However, since more display areas with a plurality of matrices are actually included, the total area of the display areas 62a formed in the first transparent display 60a is equal to the total area of the display areas 64a formed in the second transparent display 60b.

Similarly, in the transparent double-sided display 50 of the second embodiment, the display areas 52a of the first transparent display 50a and the display areas 54a of the second transparent display 50b are formed in the same repetitive pattern. Therefore, the first transparent display 50a and the second transparent display 50b can be manufactured with the same mask pattern, and thus the production efficiency can be improved.

Similarly, in the transparent double-sided display 60 of the second embodiment, the display areas 62a of the first transparent display 60a and the display areas 64a of the second transparent display 60b are formed in the same repetitive pattern. Therefore, the first transparent display 60a and the second transparent display 60b can be manufactured with the same mask pattern, and thus the production efficiency can be improved.

### Third Embodiment

Hereinafter, a third embodiment of a display device according to the present disclosure will be described with reference to the drawings.

### (Structure of Transparent Double-Sided Display of Embodiment)

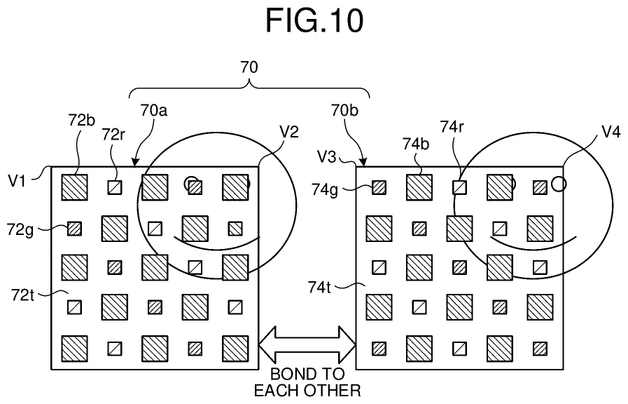

The structure of a transparent double-sided display 70 of the third embodiment will be described with reference to FIG. 10. FIG. 10 is a diagram illustrating a schematic structure of the transparent double-sided display according to the third embodiment.

In the case of a typical full-color display, light emitting areas of three colors of RGB are formed, and these light emitting areas are combined to perform full-color display. Therefore, in order to accurately reproduce a color that is desired to be displayed, it is desirable to make the light emission intensities of the three colors of RGB uniform. With this regard, the present embodiment has taken a measure against a case where it is difficult to make the light emission intensities of the three colors of RGB uniform.

The transparent double-sided display 70 of the present embodiment has a structure in which a first transparent display 70a and a second transparent display 70b are bonded to each other.

In the first transparent display 70a, display areas having a rectangular dot shape are formed as described with reference to FIG. 9A. Each of the display areas is formed of a light emitting element that emits light of one of the three colors of RGB. In other words, the one or more first light emitting elements include one or more third light emitting elements emitting light in a first color, and one or more fourth light emitting elements emitting light in a second color different from the first color. Here, it is assumed that, in the light emitting element in use, the light emission intensity of blue is lower than the light emission intensities of red and green. The blue is an example of the second color in the present disclosure. The red or the green is an example of the first color in the present disclosure. In such a case, in the display areas of the first transparent display 70a, a blue light emitting element 72b is formed to have an area larger than the areas of a red light emitting element 72r and a green light emitting element 72g. In other words, areas of the one or more third light emitting elements are larger than areas of the one or more fourth light emitting elements. Furthermore, a transmission area 72t is formed in gap parts between the display areas.

Similarly, also in the second transparent display 70b, display areas having a rectangular dot shape are formed. A transmission area 72t is formed in gap parts between the display areas. In the display areas of the second transparent display 70b, a blue light emitting element 74b is formed to have an area larger than the areas of a red light emitting element 74r and a green light emitting element 74g. Furthermore, a transmission area 74t is formed in gap parts between the display areas.

The total area of blue light emitting elements 72b formed in the first transparent display 70a is equal to the total area of blue light emitting elements 74b formed in the second transparent display 70b. Moreover, the total area of red light emitting elements 72r and green light emitting elements 72g formed in the first transparent display 70a is equal to the total area of red light emitting elements 74r and green light emitting elements 74g formed in the second transparent display 70b. Note that, in FIG. 10, only display areas of five rows and five columns are extracted and displayed from the display areas formed in each of the first transparent display 70a and the second transparent display 70b. However, since more display areas with a plurality of matrices are actually included, the total area of the display areas formed in the first transparent display 70a is equal to the total area of the display areas formed in the second transparent display 70b.

The transparent double-sided display 70 is formed by bonding in such a manner that the upper left vertex V1 of the first transparent display 70a and the upper right vertex V4 of the second transparent display 70b coincide with each other and that the upper right vertex V2 of the first transparent display 70a and the upper left vertex V3 of the second transparent display 60b coincide with each other. At this point, bonding is performed in such a manner that the blue light emitting elements 72b of the first transparent display 70a and the red light emitting elements 74r or the green light emitting elements 74g of the second transparent display 70b overlap each other and that the red light emitting elements 72r or the green light emitting elements 72g of the first transparent display 70a and the blue light emitting elements 74b of the second transparent display 70b overlap each other.

Since the area of the blue light emitting elements 72b having a low light emission intensity is larger than the area of the red light emitting elements 72r and the green light emitting elements 72g in the transparent double-sided display 70 formed in the above manner, the light emission intensities of RGB can be made uniform when color signals having equal RGB values are displayed.

Note that, in the present embodiment, the types of the light emitting element is not limited to RGB. For example, it is possible to similarly apply to a display device having light emitting elements of colors other than the three colors such as RGBY or RGBW.

### Operation and Effect of Third Embodiment

As described above, in the transparent double-sided display 70 of the second embodiment, the red light emitting elements 72r, the green light emitting elements 72g, and the blue light emitting elements 74b emit light in a plurality of display colors corresponding to different color signals, and in a case where the light emission intensities of the display colors are different, the emission area of light emitting elements corresponding to a display color having a low light emission intensity is large. Therefore, even in a case where the light emission intensities of the light emitting elements corresponding to respective color signals are different for a plurality of different color signals, the light emission intensities of RGB can be made uniform. Accordingly, color reproducibility in the transparent double-sided display 70 can be enhanced.

According to a mobile structure of a display device and a display device of the present disclosure, high transmittance can be ensured when two transparent double-sided displays are bonded to each other.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A display device comprising:
a first transparent display including one or more first transmission areas that transmit background light and one or more first non-transmission areas that include one or more first light emitting elements and do not transmit the background light, the one or more first light emitting elements performing information display ordered from an outside; and
a second transparent display bonded to the first transparent display, the second transparent display including one or more second transmission areas that transmit background light and one or more second non-transmission areas that include one or more second light emitting elements and do not transmit the background light, the one or more second light emitting elements performing information display ordered from an outside, wherein
the one or more second non-transmission areas include a third non-transmission area, the one or more first non-transmission areas include a fourth non-transmission area overlapping the third non-transmission area, and an area of the third non-transmission area is smaller than an area of the fourth non-transmission area, and
the third non-transmission area is hidden by the fourth non-transmission area when viewing the display device while facing the first transparent display.

2. The display device according to claim 1, wherein
the one or more first non-transmission areas and the one or more second non-transmission areas are each formed in a stripe shape.

3. The display device according to claim 1, wherein
the one or more first non-transmission areas and the one or more second non-transmission areas are each formed in a lattice shape.

4. The display device according to claim 1, wherein
the one or more first non-transmission areas and the one or more second non-transmission areas are each formed in a dotted shape.

5. The display device according to claim 1, wherein
the one or more first non-transmission areas include a plurality of first non-transmission areas including a fifth non-transmission area and a sixth non-transmission area having a different size than the fifth non-transmission area, and the plurality of first non-transmission areas form a first repetitive pattern,
the one or more second non-transmission areas include a plurality of second non-transmission areas including a seventh non-transmission area and a eighth non-transmission area having a different size than the seventh non-transmission area, and the plurality of second non-transmission areas form a second repetitive pattern, and
areas of the one or more first transmission areas located in the first repetitive pattern is equal to areas of the one or more second transmission areas located in the second repetitive pattern.

6. The display device according to claim 5, wherein
the first repetitive pattern and the second repetitive pattern are same.

7. The display device according to claim 1, wherein
in a case where a total area of the one or more first non-transmission areas is larger than a total area of the one or more second non-transmission areas, the second transparent display is disposed on a side where surrounding illuminance is lower.

8. The display device according to claim 1, wherein
in a case where a total area of the one or more first non-transmission areas is smaller than a total area of the one or more second non-transmission areas, the first transparent display is disposed on a side where surrounding illuminance is lower.

9. The display device according to claim 1, wherein
the one or more first light emitting elements include one or more third light emitting elements emitting light in a first color, and one or more fourth light emitting elements emitting light in a second color different from the first color, and
a light emission intensity of the first color is smaller than a light emission intensity of the second color, and areas of the one or more third light emitting elements are larger than areas of the one or more fourth light emitting elements.

10. The display device according to claim 1, wherein
areas of where the one or more first transmission areas and the one or more second transmission areas overlap each other are unchanged even in a case where misalignment corresponding to a difference between an area of the one or more first non-transmission areas and an area of the one or more second non-transmission areas occurs when the first transparent display and the second transparent display are bonded to each other such that the fourth non-transmission area included in the one or more first non-transmission areas and the third non-transmission area included in the one or more second non-transmission areas overlap each other.

11. The display device according to claim 1, wherein
the one or more first non-transmission areas further include first transparent electrodes via which voltages are supplied to cause the one or more first light emitting elements to emit, and
the one or more second non-transmission areas further include second transparent electrodes via which voltages are supplied to cause the one or more second light emitting elements to emit.

12. The display device according to claim 1, wherein
the first transparent display and the second transparent display are bonded to each other by a transparent adhesive.
